(19) United States
(12) Patent Application Publication
(10) Pub. No.: US 2024/0027885 A1
(43) Pub. Date: Jan. 25, 2024

(54) LASER PROJECTION APPARATUS

(71) Applicant: HISENSE LASER DISPLAY CO., LTD, Qingdao (CN)

(72) Inventors: Wei LI, Qingdao (CN); Youliang TIAN, Qingdao (CN); Xianrong LIU, Qingdao (CN); Xin ZHANG, Qingdao (CN); Zinan ZHOU, Qingdao (CN); Yao LU, Qingdao (CN)

(73) Assignee: HISENSE LASER DISPLAY CO., LTD, Qingdao (CN)

(21) Appl. No.: 18/477,016

(22) Filed: Sep. 28, 2023

Related U.S. Application Data
(63) Continuation of application No. PCT/CN2022/113950, filed on Aug. 22, 2022.

(30) Foreign Application Priority Data
Sep. 6, 2021 (CN) 202111037630.2
Sep. 9, 2021 (CN) 202111056654.2
Sep. 18, 2021 (CN) 202122280816.2

(51) Int. Cl. G03B 21/20

(52) U.S. Cl. CPC G03B 21/2033; G03B 21/2013; G03B 21/2066; G03B 21/2073

(57) ABSTRACT

A laser projection apparatus includes a laser source assembly, a light modulation assembly, and a projection lens. The laser source assembly includes a laser device, and the laser device includes a base plate, at least one frame, and a plurality of light-emitting chips. At least one accommodating space is defined between the at least one frame and the base plate. A region of the base plate located in the at least one accommodating space includes a first region and a second region. The second region is located on at least one side of the first region. An operating parameter of each light-emitting chip in the first region is less than an operating parameter of each light-emitting chip in the second region, and the operating parameter includes at least one of a photothermal conversion efficiency or a wavelength of the emitted laser beam.

### CROSS-REFERENCE TO RELATED APPLICATIONS

This application is a continuation application of International Patent Application No. PCT/CN2022/113950, filed on Aug. 22, 2022, which claims priority to Chinese Patent Application No. 202111037630.2, filed on Sep. 6, 2021; Chinese Patent Application No. 202111056654.2, filed on Sep. 9, 2021; and Chinese Patent Application No. 202122280816.2, filed on Sep. 18, 2021, which are incorporated herein by reference in their entireties.

### TECHNICAL FIELD

The present disclosure relates to the field of display technologies, and in particular, to a laser projection apparatus.

### BACKGROUND

Laser projection apparatuses include a laser source assembly, a light modulation assembly, and a projection lens. Illumination beams provided by the laser source assembly are modulated by the light modulation assembly to become projection beams, and the projection beams are projected onto a screen or a wall by the projection lens, so as to display a projection image. A laser device in the laser source assembly includes a plurality of light-emitting chips arranged in an array, and the plurality of light-emitting chips are configured to emit laser beams, so as to form the illumination beams.

### SUMMARY

A laser projection apparatus is provided. The laser projection apparatus includes a laser source assembly, a light modulation assembly, and a projection lens. The laser source assembly is configured to provide illumination beams, and the illumination beams include laser beams of three primary colors. The light modulation assembly is configured to modulate the illumination beams with an image signal, so as to obtain projection beams. The projection lens is configured to project the projection beams into an image. The laser source assembly includes a laser device, and the laser device includes a base plate, at least one frame, and a plurality of light-emitting chips. The at least one frame is located on the base plate, and at least one accommodating space is defined between the at least one frame and the base plate. The plurality of light-emitting chips are disposed on the base plate and located in the at least one accommodating space. The plurality of light-emitting chips are configured to emit laser beams. The laser beams exit from the accommodating space in a direction away from the base plate, so as to constitute the illumination beams. The region of the base plate located in the at least one accommodating space includes a first region and a second region. The second region is located on at least one side of the first region, and two or more light-emitting chips in the corresponding region are arranged in a row. An operating parameter of each light-emitting chip in the first region is less than an operating parameter of each light-emitting chip in the second region, and the operating parameter includes at least one of a photothermal conversion efficiency or a wavelength of the emitted laser beam.

### BRIEF DESCRIPTION OF THE DRAWINGS

FIG. 1 is a diagram showing a structure of a laser projection apparatus, in accordance with some embodiments;

FIG. 2 is a timing diagram of a laser source assembly in a laser projection apparatus, in accordance with some embodiments;

FIG. 3 is a diagram showing a beam path of a laser projection apparatus, in accordance with some embodiments;

FIG. 4 is a diagram showing an arrangement of micromirrors in a digital micromirror device, in accordance with some embodiments;

FIG. 5 is a diagram showing a swing position of a micromirror in the digital micromirror device shown in FIG. 4;

FIG. 6 is a schematic diagram showing operation of micromirrors, in accordance with some embodiments;

FIG. 7 is a diagram showing another structure of a laser projection apparatus, in accordance with some embodiments;

FIG. 8 is a diagram showing a structure of an optical filter portion, in accordance with some embodiments;

FIG. 9 is a diagram showing a structure of a laser source in the related art;

FIG. 10 is a diagram showing a structure of a laser device, in accordance with some embodiments;

FIG. 11 is a diagram showing a structure of another laser device, in accordance with some embodiments;

FIG. 12 is a diagram showing a structure of yet another laser device, in accordance with some embodiments;

FIG. 13 is a diagram showing a structure of yet another laser device, in accordance with some embodiments;

FIG. 14 is a diagram showing a structure of yet another laser device, in accordance with some embodiments;

FIG. 15 is a diagram showing a structure of yet another laser device, in accordance with some embodiments;

FIG. 16 is a diagram showing a structure of yet another laser device, in accordance with some embodiments;

FIG. 17 is a diagram showing a structure of yet another laser device, in accordance with some embodiments;

FIG. 18 is a diagram showing a structure of yet another laser device, in accordance with some embodiments;

FIG. 19 is a sectional view of the laser device in FIG. 13 taken along the line BB;

FIG. 20 is a diagram showing a structure of yet another laser device, in accordance with some embodiments;

FIG. 21 is a diagram showing a structure of yet another laser device, in accordance with some embodiments;

FIG. 22 is a diagram showing a structure of yet another laser device, in accordance with some embodiments;

FIG. 23 is a diagram showing a structure of yet another laser device, in accordance with some embodiments;

FIG. 24 is a top view of yet another laser device, in accordance with some embodiments;

FIG. 25 is a top view of yet another laser device, in accordance with some embodiments;

FIG. 26 is a top view of yet another laser device, in accordance with some embodiments;

FIG. 27 is a diagram showing a structure of yet another laser device, in accordance with some embodiments;

FIG. 28 is a diagram showing a structure of yet another laser device, in accordance with some embodiments;

FIG. 29 is a diagram showing a structure of yet another laser device, in accordance with some embodiments;

FIG. 30 is a diagram showing a structure of yet another laser device, in accordance with some embodiments; and

FIG. 31 is a diagram showing a structure of yet another laser device, in accordance with some embodiments.

### DETAILED DESCRIPTION

Some embodiments of the present disclosure will be clearly and completely described below with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only and are not to be construed as indicating or implying the relative importance or implicitly indicating the number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled,” “connected,” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The embodiments disclosed herein are not necessarily limited to the content herein.

The phrase “at least one of A, B, and C” has the same meaning as the phrase “at least one of A, B, or C,” both including the following combinations of A, B, and C: only A, only B, only C, a combination of A and B, a combination of A and C, a combination of B and C, and a combination of A, B, and C.

The use of the phrase “applicable to” or “configured to” herein means an open and inclusive expression, which does not exclude devices that are applicable to or configured to perform additional tasks or steps.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system).

In some embodiments of the present disclosure, a laser projection apparatus is provided. As shown in FIG. 1, the laser projection apparatus 1000 includes a laser source assembly 1, a light modulation assembly 2, and a projection lens 3. The laser source assembly 1 is configured to provide illumination beams. The light modulation assembly 2 is configured to modulate the illumination beams provided by the laser source assembly 1 with an image signal, so as to obtain projection beams. The projection lens 3 is configured to project the projection beams into an image on a screen or a wall.

The laser source assembly 1, the light modulation assembly 2, and the projection lens 3 are sequentially connected in a propagation direction of beams. In some examples, an end of the light modulation assembly 2 is connected to the laser source assembly 1, and the laser source assembly 1 and the light modulation assembly 2 are arranged in an exit direction (referring to the M direction shown in FIG. 1) of the illumination beams of the laser projection apparatus 1000. Another end of the light modulation assembly 2 is connected to the projection lens 3, and the light modulation assembly 2 and the projection lens 3 are arranged in an exit direction (referring to the N direction shown in FIG. 1) of the projection beams of the laser projection apparatus 1000.

In some examples, as shown in FIG. 1, the exit direction M of the illumination beams of the laser projection apparatus 1000 is substantially perpendicular to the exit direction N of the projection beams of the laser projection apparatus 1000. In this way, the structural arrangement of the laser projection apparatus 1000 may be made reasonable, and a length of a beam path of the laser projection apparatus 1000 in a direction (e.g., the direction M or the direction N) is prevented from being too long.

In some embodiments, the laser source assembly 1 may sequentially provide beams of three primary colors (i.e., beams of red color, green color and blue color). In some other embodiments, the laser source assembly 1 may simultaneously output the beams of three primary colors, so as to continuously emit white beams. Of course, the illumination beams provided by the laser source assembly 1 may also include beams other than beams of the three primary colors, such as beams of yellow. The laser source assembly 1 includes a laser device. The laser device may emit laser beams of at least one color, such as blue laser beams.

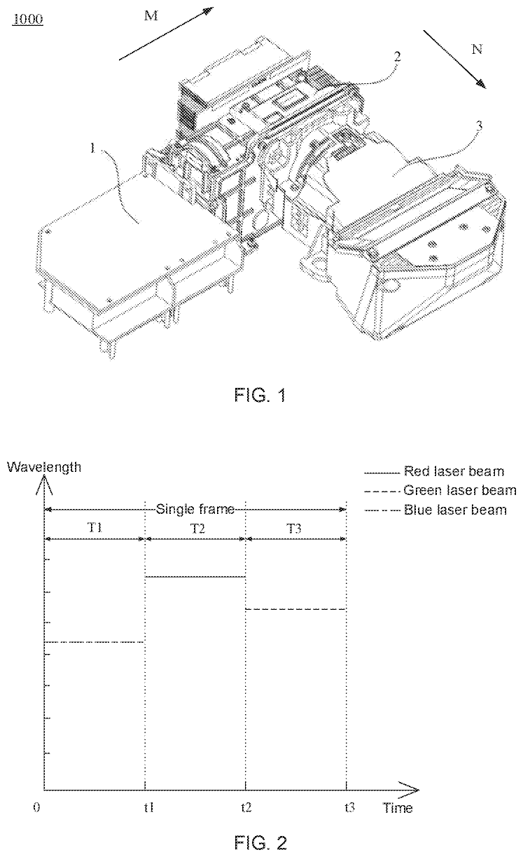

In some examples, as shown in FIG. 2, during a projection process of a frame of a target image, the laser source assembly 1 may sequentially output blue laser beams, red laser beams, and green laser beams. For example, the laser source assembly 1 outputs the blue laser beams in a first period T1, the red laser beams in a second period T2, and the green laser beams in a third period T3. In such example, time for the laser source assembly 1 to accomplish the sequential output of each of three primary color beams once is a cycle for the laser source assembly 1 to output the three primary color beams. In a display cycle of the frame of the target image, the laser source assembly 1 performs the sequential output of each of three primary color beams once. Therefore, the display cycle of the frame of the target image and the cycle for the laser source assembly 1 to output the three primary color beams are equal and are both equal to a sum of the first period T1, the second period T2, and the third period T3. In such example, due to a phenomenon of visual persistence of human eyes, the human eyes will superimpose the colors of the blue laser beams, red laser beams, and green laser beams that are sequentially output. Therefore, what the human eyes see is white beams formed by mixing the beams of three primary colors.

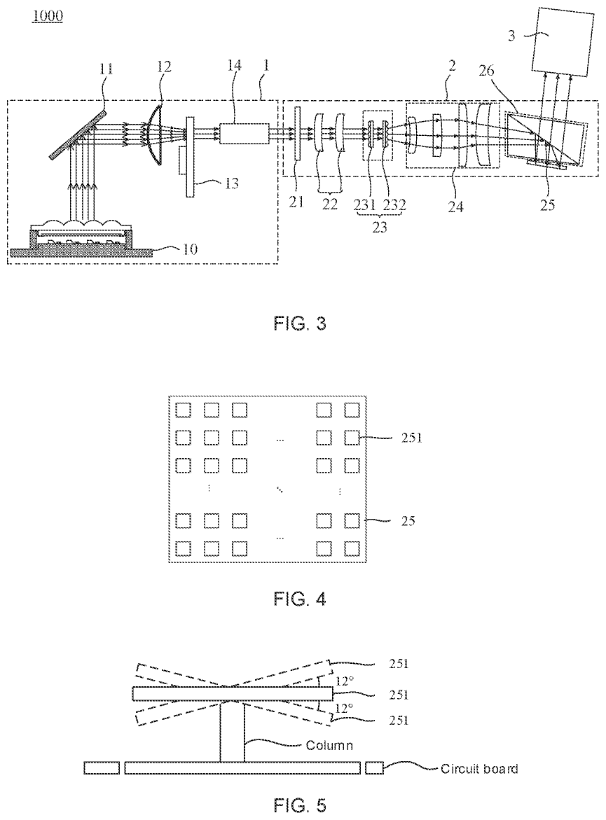

The illumination beams emitted by the laser source assembly 1 enter the light modulation assembly 2. Referring to FIG. 3, the light modulation assembly 2 includes a digital micromirror device (DMD) 25.

The digital micromirror device 25 is located on a laser-exit side of the laser source assembly 1 and is configured to use an image signal to modulate the illumination beams provided by the laser source assembly 1 to obtain the projection beams and reflect the projection beams to the projection lens 3. Since the digital micromirror device 25 may control the projection beams to display different luminance or gray scales according to different pixels in the image to be displayed, so as to finally produce a projection image. The digital micromirror device 25 is also referred to as a light modulation device (or light valve). In addition, the light modulation assembly 2 may be classified as a single-chip system, a double-chip system, or a three-chip system according to the number of the digital micromirror devices 25 used in the light modulation assembly 2.

It will be noted that, in some embodiments of the present disclosure, the light modulation assembly 2 shown in FIG. 3 applies a digital light processing (DLP) projection architecture. Therefore, the light modulation device in some embodiments of the present disclosure is the digital micromirror device. However, the present disclosure does not limit the architecture applied to the light modulation assembly 2 and the type of the light modulation device.

As shown in FIG. 4, the DMD 25 includes thousands of micromirrors 251 that may be individually driven to rotate. These micromirrors 251 are arranged in an array. One micromirror 251 corresponds to one pixel in the image to be displayed. As shown in FIG. 5, in the DLP projection architecture, each micromirror 251 is equivalent to a digital switch, and may swing in a range of minus 12° to plus 12° (i.e., ±12°) or a range of minus 17° to plus 17° (i.e., ±17°) due to an action of an external force. FIG. 5 is illustrated by considering an example in which each micromirror 251 may swing in a range of minus 12° to plus 12° (i.e., ±12°).

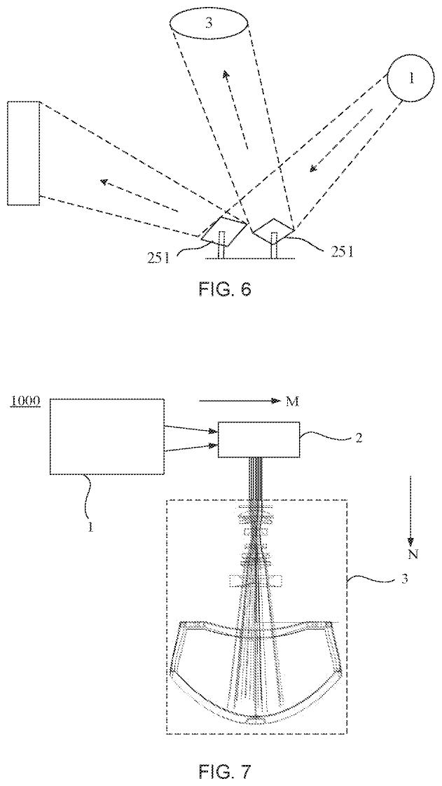

As shown in FIG. 6, a laser beam reflected by the micromirror 251 at a negative deflection angle is referred to as an OFF laser beam. The OFF laser beam is an ineffective laser beam. A laser beam reflected by the micromirror 251 at a positive deflection angle is referred to as an ON laser beam. The ON laser beam is an effective beam reflected by the micromirror 251 on a surface of the DMD 25 when it receives irradiation of the illumination beams, and the ON laser beam enters the projection lens 3 at a positive deflection angle for projection imaging. An ON state of the micromirror 251 is a state that the micromirror 251 is in and may be maintained when the illumination beams emitted by the laser source assembly 1 may enter the projection lens 3 after being reflected by the micromirror 251. That is to say, the micromirror 251 is in a state of the positive deflection angle. An OFF state of the micromirror 251 is a state that the micromirror 251 is in and may be maintained when the illumination beams emitted by the laser source assembly 1 does not enter the projection lens 3 after being reflected by the micromirror 251. That is to say, the micromirror 251 is in a state of the negative deflection angle.

In a display cycle of a frame of an image, some or all of the micromirrors 251 may be switched at least once between the ON state and the OFF state, so that gray scales of pixels in the frame image are achieved according to durations that the micromirrors 251 are in the ON state and the OFF state. For example, in a case where the pixels have 256 gray scales from 0 to 255, the micromirrors 251 corresponding to a gray scale 0 are each in the OFF state in an entire display cycle of a frame of an image, the micromirrors 251 corresponding to a gray scale 255 are each in the ON state in the entire display cycle of the frame of the image, and the micromirrors 251 corresponding to a gray scale 127 are each in the ON state for a half of time and in the OFF state for another half of time in the display cycle of the frame of the image. Therefore, by controlling a state that each micromirror 251 in the DMD 25 is in and a duration of each state in the display cycle of a frame of an image through the image signals, luminance (the gray scale) of the pixel corresponding to the micromirror 251 may be controlled, thereby modulating the illumination beams projected onto the DMD 25.

In some embodiments, with continued reference to FIG. 3, the light modulation assembly 2 further includes a diffusion sheet 21, a first lens group 22, a fly-eye lens group 23, a second lens group 24, and a prism group 26. It will be noted that the light modulation assembly 2 may also include fewer or more components than the components shown in FIG. 3, and the present disclosure is not limited thereto.

The diffusion sheet 21 is located on the laser-exit side of the laser source assembly 1 and configured to diffuse the illumination beams from the laser source assembly 1. The first lens group 22 is located on a laser-exit side of the diffusion sheet 21 and configured to converge the illumination beams diffused by the diffusion sheet 21. The fly-eye lens group 23 is located on a laser-exit side of the first lens group 22 and configured to homogenize the illumination beams converged by the first lens group 22. The second lens group 24 is located on a laser-exit side of the fly-eye lens group 23 and configured to transmit the illumination beams homogenized by the fly-eye lens group 23 to the prism group 26. The prism assembly 26 is configured to reflect the illumination beams to the digital micromirror device 25.

In some embodiments, as shown in FIG. 3, the fly-eye lens group 23 includes a first fly-eye lens 231 and a second fly-eye lens 232 arranged opposite to each other in a propagation direction of the illumination beams. A laser-incident surface of the first fly-eye lens 231 and a laser-exit surface of the second fly-eye lens 232 each include micro lenses arranged in an array. After passing through the first fly-eye lens 231, the illumination beams converged by the first lens group 22 are converged into multiple thin beams (i.e., laser beams with small beam spots) by different micro lenses on the laser-incident surface of the first fly-eye lens 231, and each are focused on a center of each micro lens of the second fly-eye lens 232. The plurality of micro lenses on the laser-exit surface of the second fly-eye lens 232 may diffuse the multiple thin beams, so that the multiple thin beams may become multiple wide beams (i.e., laser beams with big beam spots). The beam spots of the multiple wide beams overlap with each other. Therefore, the uniformity and illumination brightness of the illumination beams are improved after the illumination beams pass through the first fly-eye lens 231 and the second fly-eye lens 232.

As shown in FIG. 7, the projection lens 3 includes a combination of a plurality of lenses, which are usually divided by group and are divided into a three-segment combination including a front group, a middle group and a rear group or a two-segment combination including a front group and a rear group. The front group is a lens group proximate to a laser-exit side (e.g., a side of the projection lens 3 away from the light modulation assembly 2 in the N direction in FIG. 7) of the laser projection apparatus 1000, and the rear group is a lens group proximate to a laser-exit side (e.g., a side of the projection lens 3 proximate to the light modulation assembly 2 in the opposite direction of the N direction in FIG. 7) of the light modulation assembly 2.

Referring to FIG. 3, the laser source assembly 1 includes a laser device 10, a combining lens group 11, a converging lens group 12, an optical filter portion 13, and a light homogenizing component 14. The laser device 10 is configured to provide the illumination beams. The combining lens group 11 is disposed on a laser-exit side of the laser device 10 and configured to reflect the illumination beams provided by the laser device 10 to the converging lens group 12. The converging lens group 12 is disposed on a laser-exit side of the combining lens group 11 and configured to converge the illumination beams from the combining lens group 11. The optical filter portion 13 is disposed on a laser-exit side of the converging lens group 12 and configured to filter the illumination beams converged by the converging lens group 12, so as to sequentially output beams of three primary colors (i.e., red, green, blue). The light homogenizing component 14 is located on a laser-exit side of the optical filter portion 13 and configured to homogenize the illumination beams filtered by the optical filter portion 13.

In some embodiments, the combining lens group 11 may be a dichroic mirror. In a case where the laser source assembly 1 outputs the beams of three primary colors (that is, the laser device 10 outputs the beams of three primary colors) simultaneously or sequentially, the combining lens group 11 may adjust the red laser beams, green laser beams, and blue laser beams emitted by the laser device 10 to a substantially same beam path and reflect them to the converging lens group 12.

In some embodiments, the converging lens group 12 may include at least one planoconvex lens, and a convex surface of the at least one planoconvex lens faces a laser-exit direction of the combining lens group 11. Of course, the converging lens group 12 may also include a plurality of convex lenses, and the present disclosure is not limited thereto.

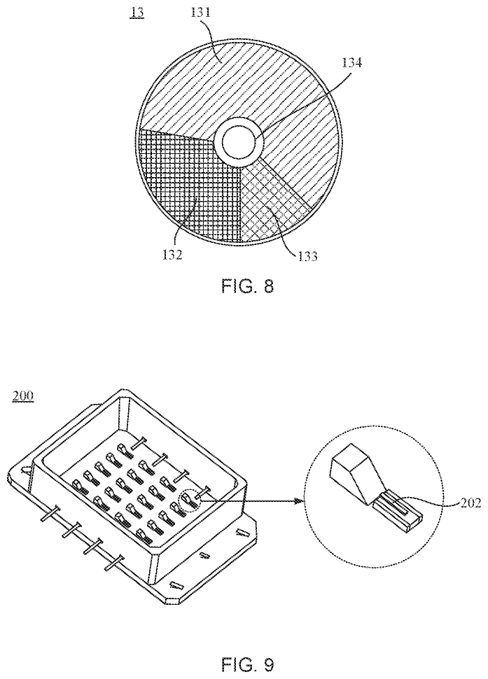

In some embodiments, as shown in FIG. 8, the optical filter portion 13 includes a green optical filter 131, a blue optical filter 132, a red optical filter 133, and a driving portion 134. The driving portion 134 is configured to drive the plurality of optical filters to rotate, so that the illumination beams emitted by the laser device 10 may be filtered by the optical filters of different colors during a display period of a frame of an image. In some examples, in a case where the laser device 10 simultaneously outputs the beams of three primary colors, and the optical filter portion 13 is rotated to a position where the red optical filter 133 covers the beam spots of the beams of the three primary colors, beams of other colors except for the red laser beams in the beams of three primary colors are blocked, while the red laser beams pass through the red optical filter 133. Of course, the optical filter portion 13 may also include optical filters of other colors, and the present disclosure is not limited thereto.

In some embodiments, the light homogenizing component 14 may include a fish-eye lens or a light pipe. In some examples, the light homogenizing component 14 includes a fly-eye lens. For the structure of the light homogenizing component 14, reference may be made to the structure of the above fly-eye lens group 23, and details will not be repeated herein. In some other examples, the light homogenizing component 14 includes a light pipe. The light pipe may be a tubular device (i.e., a hollow light pipe) spliced by four planar reflecting sheets. The illumination beams are reflected multiple times inside the light pipe, so as to achieve the effect of homogenizing light. Of course, the light homogenizing component 14 may also include a solid light pipe. For example, a light inlet and light outlet of the light pipe are in a shape of a rectangle with a same shape and area. The illumination beams enter the light pipe from the light inlet of the light pipe and then exit from the light outlet of the light pipe, so that the illumination beams and the beam spot of the illumination beams may be homogenized during the illumination beams passing through the light pipe.

It will be noted that, in a case where the light homogenizing component 14 includes the light pipe, the light modulation assembly 2 may not be provided with a light pipe. In a case where the light homogenizing component 14 is other components other than the light pipe, the light modulation assembly 2 may be provided with the above light pipe, so as to receive and homogenize the illumination beams from the laser source assembly 1.

In the related art, as shown in FIG. 9, a laser device 200 includes a plurality of light-emitting chips 202 configured to emit laser beams, so as to form illumination beams. In a case where the laser device 200 includes a large number of light-emitting chips 202, the plurality of light-emitting chips 202 may generate a lot of heat when emitting laser beams, and the heat accumulated in the laser device 200 may cause junction temperatures of the light-emitting chips 202 to increase. The junction temperature refers to an actual operating temperature of the semiconductor in the light-emitting chip 202. The increase in the junction temperature may cause a decrease in the performance of the light-emitting chip 202. For example, the increase in the junction temperature may cause a decrease in the photoelectric conversion efficiency, service life, and reliability of the light-emitting chip 202. In a case where the laser device 200 operates at a high junction temperature for a long time, catastrophic optical damage (COD) will occur to the light-emitting chip. Therefore, in the related art, the laser device 200 usually includes a few light-emitting chips 202, which may cause low luminance of the illumination beams provided by the laser device 200, so that the display effect of the projection image may be affected.

In view of the above problems, it is found through research that: in the related art, the plurality of light-emitting chips 202 of the laser device 200 are arranged in an array of multiple rows and columns, and the arrangement is relatively regular and compact. In this way, in the plurality of light-emitting chips 202, the overlapping degree of heat dissipation regions of the light-emitting chips 202 in a middle region is high, and the heat generated by the light-emitting chips 202 in the middle region is difficult to dissipate. For example, a region between two adjacent light-emitting chips 202 in the middle region may receive heat from at least two light-emitting chips 202, and the heat generated by the light-emitting chips 202 may be significantly concentrated in the middle region, as a result, the heat of the light-emitting chips 202 in the middle region is difficult to dissipate rapidly. However, the overlapping degree of the heat dissipation regions of the light-emitting chips 202 in an edge region is low, and the heat generated by the light-emitting chips 202 in the edge region is easy to dissipate. For example, the heat of a light-emitting chip 202 in the edge region may transmit to the outside of the light-emitting chip 202. Since there are no components that may generate heat outside the light-emitting chip 202, the heat of the light-emitting chip 202 in the edge region is easy to dissipate rapidly. Therefore, compared with the light-emitting chips 202 in the edge region, the light-emitting chips 202 in the middle region is more prone to high junction temperature and thermal damage such as COD.

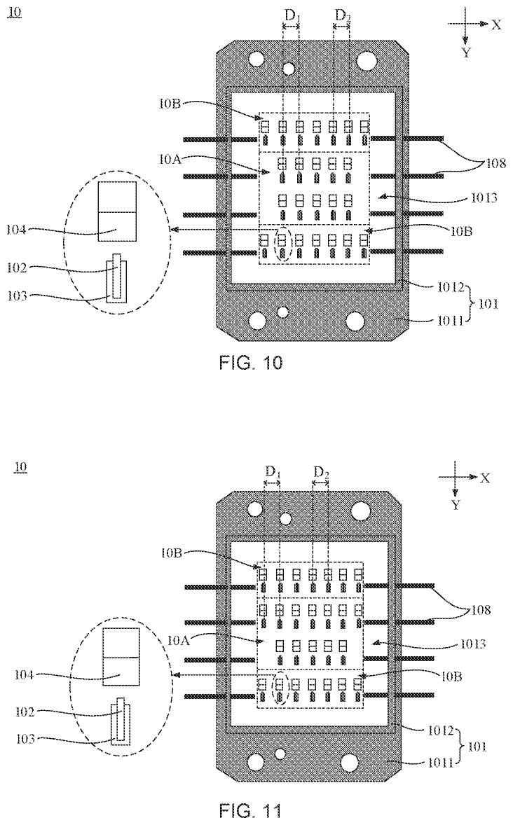

On this basis, as shown in FIG. 10, a laser projection apparatus 1000 provided by some embodiments of the present disclosure includes a laser device 10, and the laser device 10 includes a plurality of light-emitting chips 102. By adjusting the arrangement manner of the plurality of light-emitting chips 102 in the laser device 10, at least one of an arrangement density or the number of the light-emitting chips 102 in the middle region (e.g., a first region 10A) may be less than that of the light-emitting chips 102 in the edge region (e.g., a second region 10B), so as to reduce the overlapping degree of the heat dissipation regions of the light-emitting chips 102 in the middle region and avoid the thermal damage to the light-emitting chips 102 in the middle region, thereby improving the reliability of the laser device 10. Moreover, by improving the reliability of the laser device 10, a large number of light-emitting chips 102 may be arranged in the laser device 10, so as to increase the luminance of the illumination beams, so that the display effect of the projection image displayed by the laser projection apparatus 1000 may be improved.

In some embodiments, as shown in FIG. 10, the laser device 10 includes a base plate 1011, a frame 1012, and a plurality of light-emitting chips 102.

The frame 1012 is located on the base plate 1011, and an accommodating space 1013 is defined between the frame 1012 and the base plate 1011.

The plurality of light-emitting chips 102 are disposed on the base plate 1011 and located in the accommodating space 1013 and configured to emit the laser beams. The laser beams exit from the accommodating space 1013 in a direction away from the base plate 1011, so as to form the illumination beams.

The structure composed of the base plate 1011 and the frame 1012 may be referred to as a tube shell 101, and the accommodating space 1013 defined between the base plate 1011 and the frame 1012 is the accommodating space 1013 of the tube shell 101. A region of the base plate 1011 located in the accommodating space 1013 is a region where the plurality of light-emitting chips 102 are disposed.

The region of the base plate 1011 located in the accommodating space 1013 includes a first region 10A and a second region 10B, and the plurality of light-emitting chips 102 satisfy at least one of the following: the number of light-emitting chips 102 in the first region 10A is less than the number of light-emitting chips 102 in the second region 10B; or, the arrangement density of the light-emitting chips 102 in the first region 10A is less than the arrangement density of the light-emitting chips 102 in the second region 10B.

In some embodiments, the second region 10B is located on at least one side of the first region 10A. In some examples, the second region 10B may surround the first region 10A. For example, the second region 10B surrounds the first region 10A, or half surrounds the first region 10A, or is located on two opposite sides of the first region 10A. Alternatively, the second region 10B may also be located on a side of the first region 10A. The present disclosure does not limit the relative positional relationship between the first region 10A and the second region 10B. The following is introduced by considering an example in which the second region 10B is located on two opposite sides of the first region 10A in a second direction Y.

For example, as shown in FIG. 10, the light-emitting chips 102 in the first region 10A and the light-emitting chips 102 in the second region 10B use a first direction X as a row direction and the second direction Y as a column direction, and each are arranged in a plurality of rows and columns, and the first direction X is perpendicular to the second direction Y. In this case, the plurality of light-emitting chips 102 on the base plate 1011 are arranged in a plurality of rows. In this way, the light-emitting chips 102 in the second region 10B may include two rows of light-emitting chips 102 located in the first row and the last row, and the light-emitting chips 102 in the first region 10A may include the light-emitting chips 102 in other rows except the first row and the last row. For example, the plurality of light-emitting chips 102 in FIG. 10 are arranged in four rows. The first row and fourth row of light-emitting chips 102 are the light-emitting chips 102 in the second region 10B, and the second row and third row of light-emitting chips 102 are the light-emitting chips 102 in the first region 10A.

Moreover, since the second region 10B is located on two sides of the first region 10A, the first region 10A is closer to the center of the base plate 1011 than the second region 10B, and the first region 10A may also be referred to as the middle region. The second region 10B is closer to the edge of the base plate 1011 than the first region 10A, and the second region 10B may also be referred to as the edge region. In addition, the first region 10A may be in a shape of a quadrilateral (e.g., a rectangle, a square), a circle, or other regular shapes, or may be an irregular shape, and the present disclosure does not limit thereto. For ease of description, the first region 10A and the second region 10B are shown in dashed boxes in FIG. 10.

It will be noted that, the number of light-emitting chips 102 in the first region 10A may refer to the total number of light-emitting chips 102 in the first region 10A, and the number of light-emitting chips 102 in the second region 10B may refer to the total number of light-emitting chips 102 in the second region 10B. Alternatively, in a case where the light-emitting chips 102 in the first region 10A and the light-emitting chips 102 in the second region 10B each are arranged in an array of a plurality of rows and columns, the number of light-emitting chips 102 in the first region 10A may refer to the number of a row of light-emitting chips 102 in the first region 10A, and the number of light-emitting chips 102 in the second region 10B may refer to the number of a row of light-emitting chips 102 in the second region 10B.

Moreover, the arrangement density of the light-emitting chips 102 is a dense degree of the arrangement of the light-emitting chips 102, and the arrangement density may be characterized by a distance between two adjacent light-emitting chips 102. For example, the greater the distance between two adjacent light-emitting chips 102, the less the arrangement density of the light-emitting chips 102. It will be noted that, FIG. 10 is illustrated by considering an example in which the number of light-emitting chips 102 in the first region 10A is less than the number of light-emitting chips 102 in the second region 10B, and the arrangement density of the light-emitting chips 102 in the first region 10A is equal to the arrangement density of the light-emitting chips 102 in the second region 10B.

In the laser projection apparatus 1000 provided by some embodiments of the present disclosure, in a case where the arrangement manner of the plurality of light-emitting chips 102 satisfies that the number of light-emitting chips 102 in the first region 10A is less than the number of light-emitting chips 102 in the second region 10B, the total heat generated by the light-emitting chips 102 in the first region 10A is reduced, so that the heat per unit area of the first region 10A is reduced, which facilitates the rapid dissipation of the heat generated by the light-emitting chips 102 in the first region 10A. In a case where the arrangement manner of the plurality of light-emitting chips 102 satisfies that the arrangement density of the light-emitting chips 102 in the first region 10A is less than the arrangement density of the light-emitting chips 102 in the second region 10B, an area of the heat dissipation region of a single light-emitting chip 102 in the first region 10A increases, which is conducive to the rapid dissipation of the heat generated by the light-emitting chips 102 in the first region 10A. In this way, it is possible to improve the heat dissipation effect of the light-emitting chips 102 in the first region 10A and reduce the probability of thermal damage to the light-emitting chips 102 in the first region 10A due to heat accumulation, thereby improving the reliability of the laser device 10 and further improving the reliability of the laser projection apparatus 1000. Moreover, since the reliability of the laser device 10 is improved, a large number of light-emitting chips 102 may be arranged in the laser device 10 in the premise that the plurality of light-emitting chips 102 in the laser device 10 may normally operate, so as to improve the luminance of the illumination beams provided by the laser device 10, thereby improving the display effect of the projection image projected by the laser projection apparatus 1000.

The relationship between the numbers of light-emitting chips 102 in the first region 10A and the second region 10B is described below by considering an example in which the plurality of light-emitting chips 102 are arranged in four rows and the light-emitting chips 102 in the second region 10B include the first row and fourth row of light-emitting chips 102 with reference to accompanying drawings. Of course, the light-emitting chips 102 in the first region 10A and the second region 10B each may also be arranged in one row, three rows, or more rows, and the present disclosure is not limited thereto.

In some embodiments, the number of light-emitting chips 102 in the first region 10A is less than the number of light-emitting chips 102 in the second region 10B. Moreover, the arrangement density of the light-emitting chips 102 in the first region 10A is less than or equal to the arrangement density of the light-emitting chips 102 in the second region 108.

In this case, the number of at least one row of light-emitting chips 102 in the first region 10A is less than the number of at least one row of light-emitting chips 102 in the second region 10B.

In some examples, referring to FIG. 10, the number of a row of light-emitting chips 102 in the first region 10A is five, the number of a row of light-emitting chips 102 in the second region 10B is seven, and the number of each row of light-emitting chips 102 in the first region 10A is less than the number of each row of light-emitting chips 102 in the second region 10B. It will be noted that, FIG. 10 is illustrated by considering an example in which the numbers of rows of light-emitting chips 102 in the first region 10A are equal to each other, and the numbers of rows of light-emitting chips 102 in the second region 108 are equal to each other.

In some other examples, the numbers of rows of light-emitting chips 102 in the first region 10A may also be unequal to each other, and the numbers of rows of light-emitting chips 102 in the second region 10B may also be unequal to each other. For example, the number of light-emitting chips 102 in the first row is seven, the number of light-emitting chips 102 in the fourth row is six, the number of light-emitting chips 102 in the second row is four, and the number of light-emitting chips 102 in the third row is five.

In yet some other examples, referring to FIG. 11, the number of light-emitting chips 102 in the first row is seven, the number of light-emitting chips 102 in the fourth row is seven, the number of light-emitting chips 102 in the second row is seven, and the number of light-emitting chips 102 in the third row is five. That is to say, the number of a row of light-emitting chips 102 in the first region 10A is less than the number of a row of light-emitting chips 102 in the second region 10B, and the number of another row of light-emitting chips 102 in the first region 10A is equal to the number of a row of light-emitting chips 102 in the second region 10B.

In some other embodiments, the number of light-emitting chips 102 in the first region 10A is equal to the number of light-emitting chips 102 in the second region 10B. Moreover, the arrangement density of the light-emitting chips 102 in the first region 10A is less than the arrangement density of the light-emitting chips 102 in the second region 10B.

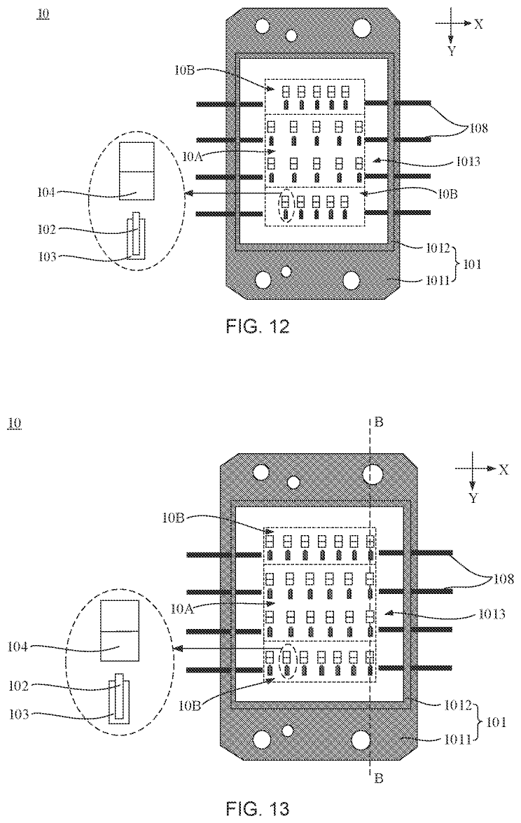

In some examples, referring to FIG. 12, the number of a row of light-emitting chips 102 in the first region 10A is equal to the number of a row of light-emitting chips 102 in the second region 108, and distances (e.g., a distance between two adjacent light-emitting chips 102 in the second direction Y) between any two adjacent rows of light-emitting chips 102 in the plurality of light-emitting chips 102 are equal to each other. And in the row direction, an arrangement length of the light-emitting chips 102 in the first region 10A is greater than an arrangement length of the light-emitting chips 102 in the second region 10B.

It will be noted that in a case where the distances between any two adjacent rows of light-emitting chips 102 in the plurality of light-emitting chips 102 are equal to each other, and the arrangement density of the light-emitting chips 102 may be adjusted by adjusting the arrangement length of the light-emitting chips 102 in the row direction. In some embodiments of the present disclosure, it is also possible to adjust the arrangement density of the light-emitting chips 102 by adjusting the distance between two adjacent rows of the light-emitting chips 102. For example, in a case where the distances between any two adjacent rows of light-emitting chips 102 in the plurality of light-emitting chips 102 are equal to each other, the arrangement density of light-emitting chips 102 in the first region 10A may be reduced by increasing the distances between any two adjacent rows of light-emitting chips 102 in the first region 10A. Of course, the arrangement density of the light-emitting chips 102 in the first region 10A may be reduced by increasing the distances between any two adjacent rows of light-emitting chips 102 and the distances between any two adjacent columns of light-emitting chips 102 in the first region 10A simultaneously, and the present disclosure is not limited thereto.

The relationship between the arrangement densities of the light-emitting chips 102 in the first region 10A and the second region 10B is described below by considering an example in which the plurality of light-emitting chips 102 are arranged in four rows, the light-emitting chips 102 in the second region 10B include the first row and the fourth row of light-emitting chips 102, and the distances between any two adjacent rows of light-emitting chips 102 in the plurality of light-emitting chips 102 are equal to each other with reference to accompanying drawings.

In some embodiments, the arrangement density of light-emitting chips 102 in the first region 10A is less than the arrangement density of light-emitting chips 102 in the second region 10B.

In some examples, the number of light-emitting chips 102 in the first region 10A is equal to the number of light-emitting chips 102 in the second region 10B. In this case, for the arrangement manner of the plurality of light-emitting chips 102, reference may be made to FIG. 12, and details will not be repeated herein.

In some other examples, the number of light-emitting chips 102 in the first region 10A is less than the number of light-emitting chips 102 in the second region 10B. In this case, referring to FIG. 13, in the row direction, the distance between two adjacent light-emitting chips 102 in the second row and third row is greater than the distance between two adjacent light-emitting chips 102 in the first row and fourth row.

It will be noted that, in some embodiments of the present disclosure, the light-emitting chips 102 in a same row may be arranged at equal intervals or may be arranged at unequal intervals. The above embodiments are described by considering an example in which the light-emitting chips 102 in a same row are arranged at equal intervals. In addition, the above embodiments are described by considering an example in which the arrangement densities of rows of light-emitting chips 102 in the first region are equal to each other, and the arrangement densities of rows of light-emitting chips 102 in the second region 10B are equal to each other. Of course, in some embodiments of the present disclosure, the arrangement densities of different rows of light-emitting chips 102 in a same region (e.g., the first region 10A or the second region may also be unequal to each other.

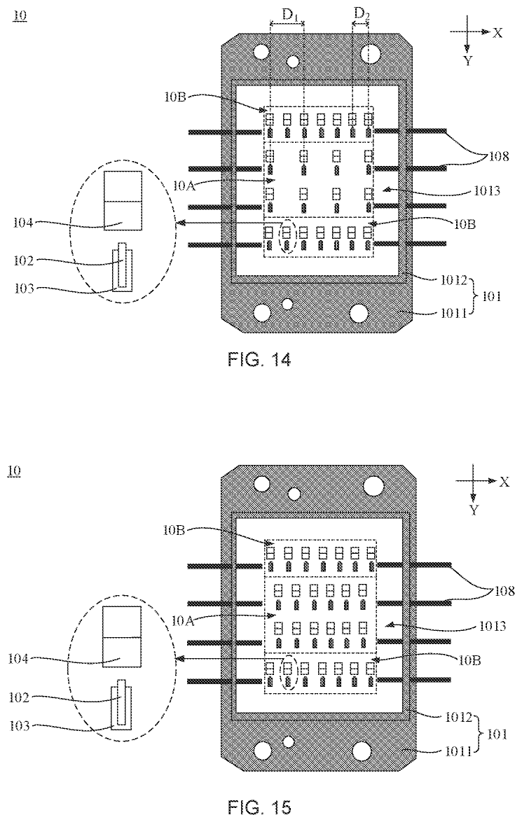

Moreover, in some embodiments of the present disclosure, the plurality of light-emitting chips 102 may be arranged in a shape of a rectangle. Here, the rectangular arrangement means that, in the plurality of rows of light-emitting chips 102, the light-emitting chips 102 located at two ends in the row direction are aligned with each other in the column direction. That is to say, an outer edge of the arrangement shape of the plurality of rows of light-emitting chips 102 is in a shape of a rectangle. For example, referring to FIGS. 13 and 14, the light-emitting chips 102 located at two ends of the four rows of light-emitting chips 102 in the first direction X are aligned with each other in the second direction Y, and the four rows of light-emitting chips 102 are arranged in a shape of a rectangle. In this way, the outer edge of the arrangement shape of the plurality of light-emitting chips 102 is regular, and when the plurality of light-emitting chips 102 are packaged with components such as the frame 1012, the operation difficulty may be reduced.

In some other embodiments, the arrangement density of the light-emitting chips 102 in the first region 10A is equal to the arrangement density of the light-emitting chips 102 in the second region 10B. In this case, the number of light-emitting chips 102 in the first region 10A is less than the number of light-emitting chips 102 in the second region 10B.

In some examples, referring to FIGS. 10 and 11, in the row direction, the distance between two adjacent light-emitting chips 102 of a row of light-emitting chips 102 in the first region 10A is equal to the distance between two adjacent light-emitting chips 102 of a row of light-emitting chips 102 in the second region 10B. In the row direction, the arrangement length of at least one row of light-emitting chips 102 in the first region 10A is less than the arrangement length of a row of light-emitting chips 102 in the second region 10B.

The plurality of rows of light-emitting chips 102 may have various relative positions. The relative positions between the plurality of rows of light-emitting chips 102 are described below with reference to the accompanying drawings.

In some embodiments, at least a portion of the light-emitting chips 102 in a row of light-emitting chips 102 in the first region 10A may be aligned in the column direction with at least a portion of the light-emitting chips 102 in a row of light-emitting chips 102 in the second region 10B. In such arrangement manner, in the first aspect, the plurality of light-emitting chips 102 are arranged regularly, which facilitates the encapsulation of the plurality of light-emitting chips 102 during the manufacturing process. In the second aspect, in a case where the plurality of light-emitting chips 102 are operating, the beam spots of the laser beams emitted by the plurality of light-emitting chips 102 are also arranged regularly, which is conducive to improving the uniformity of the illumination beams provided by the laser device 10. For example, referring to FIG. 10, all of the light-emitting chips 102 in the second row are aligned in the column direction with the second to sixth light-emitting chips 102 in the first row of light-emitting chips 102; all of the light-emitting chips 102 in the third row are aligned in the column direction with all of the light-emitting chips 102 in the second row; and the second to sixth light-emitting chips 102 in the fourth row of light-emitting chips 102 are aligned in the column direction with all of the light-emitting chips 102 in the third row.

Moreover, in such arrangement manner, the distances between two adjacent light-emitting chips 102 in the rows of light-emitting chips 102 in the row direction may be an integer multiple relationship. For example, as shown in FIGS. 10 and 11, in the row direction, a distance D₁ between two adjacent light-emitting chips 102 in a row of light-emitting chips 102 in the first region 10A is equal to a distance D₂ between two adjacent light-emitting chips 102 in a row of light-emitting chips 102 in the second region 10B. Alternatively, as shown in FIG. 14, in the row direction, the distance D₁ between two adjacent light-emitting chips 102 in a row of light-emitting chips 102 in the first region 10A is twice the distance D₂ between two adjacent light-emitting chips 102 in a row of light-emitting chips 102 in the second region 10B.

In some other embodiments, at least one row of light-emitting chips 102 in the first region 10A and at least one row of light-emitting chips 102 in the second region 10B are arranged in a staggered manner. In this way, in a case where the distance between two adjacent rows of light-emitting chips 102 is unchanged, the distance between the light-emitting chip 102 in the first region 10A and the light-emitting chip 102 in the adjacent row may be increased, so that heat dissipation area of the light-emitting chips 102 in the first region 10A may be increased, so as to avoid heat accumulation in the first region 10A.

It will be noted that the staggered arrangement of two rows of light-emitting chips 102 means that the light-emitting chips 102 in the two rows are misaligned with each other in the column direction. That is to say, at least one light-emitting chip 102 in a row of light-emitting chips 102 is misaligned in the column direction with the light-emitting chips 102 in another row of light-emitting chips 102. For example, referring to FIG. 13, in the first direction X, the first and sixth light-emitting chips 102 in the second row of light-emitting chips 102 are aligned with the first and seventh light-emitting chips 102 in the first row of light-emitting chips 102; and in the first direction X, the second to fifth light-emitting chips 102 in the second row of light-emitting chips 102 are aligned in the second direction Y with chip gaps in the first row of light-emitting chips 102. In this case, it may be said that the first row of light-emitting chips 102 and the second row of light-emitting chips 102 are arranged in a staggered manner. Here, the chip gap refers to a region where no light-emitting chip 102 is disposed in a row of light-emitting chips 102. For example, the chip gap includes a region between two adjacent light-emitting chips 102 in a same row.

In some examples, the rows of light-emitting chips 102 in the first region 10A are aligned in the column direction with each other, the rows of light-emitting chips 102 in the second region 10B are aligned in the column direction with each other, and the light-emitting chips 102 in the first region 10A are misaligned in the column direction with the light-emitting chips 102 in the second region 10B. The following is described by considering an example in which a row of light-emitting chips 102 in the second region 10B include seven light-emitting chips 102, and a row of light-emitting chips 102 in the first region 10A include six light-emitting chips 102. Referring to FIG. 15, the light-emitting chips 102 in the second and third rows in the first region 10A are aligned in the second direction Y with each other, the light-emitting chips 102 in the first and fourth rows in the second region 10B are aligned in the second direction Y with each other, and the light-emitting chips 102 in the second and third rows are aligned in the second direction Y with the chip gaps between the light-emitting chips 102 in the first and fourth rows, respectively.

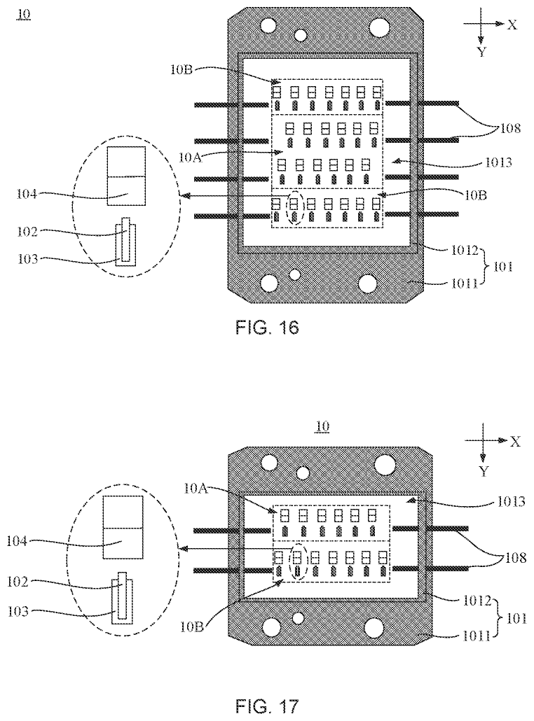

In some other examples, the light-emitting chips 102 in two adjacent rows in the plurality of light-emitting chips 102 are misaligned in the column direction with each other. It will be noted that, in such example, the light-emitting chips 102 in two non-adjacent rows in the plurality of light-emitting chips 102 may be aligned in the column direction with each other. The following is described by considering an example in which a row of light-emitting chips 102 in the second region 10B includes seven light-emitting chips 102, and a row of light-emitting chips 102 in the first region 10A includes six light-emitting chips 102. Referring to FIG. 16, except for the first row of light-emitting chips 102, a row of light-emitting chips 102 are aligned in the second direction Y with the chip gaps of a previous row of light-emitting chips 102.

It will be noted that the numbers and arrangement densities of the light-emitting chips 102 in the first region 10A and the second region 10B and relative positions of the rows of the light-emitting chips 102 in the first region 10A and the second region 10B may be combined in various ways. For example, the following is described by considering an example in which the plurality of light-emitting chips 102 are arranged in two rows, the second region 10B is located on a side of the first region 10A, and the light-emitting chips 102 in the second region 10B include the second row of light-emitting chips 102. As shown in FIG. 17, the number of light-emitting chips 102 in the first region 10A is less than the number of light-emitting chips 102 in the second region 10B, the arrangement density of the light-emitting chips 102 in the first region 10A is equal to the arrangement density of the light-emitting chips 102 in the second region 10B, and a row of light-emitting chips 102 in the first region 10A and a row of light-emitting chips 102 in the second region 10B are arranged in a staggered manner.

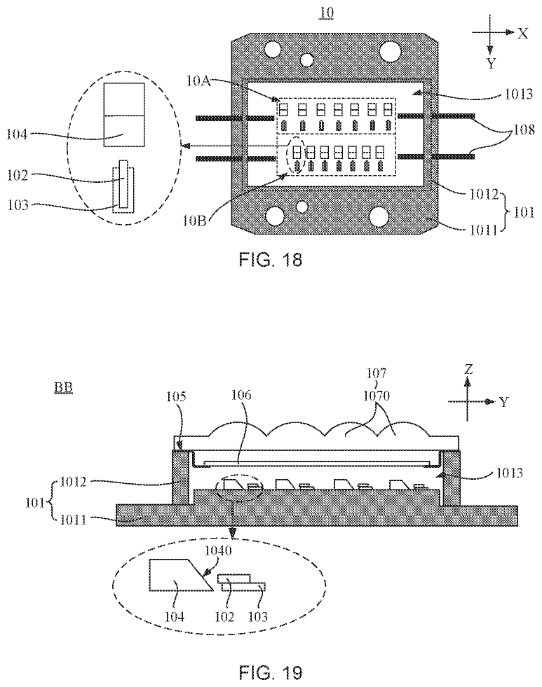

The following continues to be described by considering an example in which the plurality of light-emitting chips 102 are arranged in two rows, the second region 10B is located on a side of the first region 10A, and the light-emitting chips 102 in the second region 10B include the second row of light-emitting chips 102. As shown in FIG. 18, the number of light-emitting chips 102 in the first region 10A is equal to the number of light-emitting chips 102 in the second region 10B, the arrangement density of the light-emitting chips 102 in the first region 10A is less than the arrangement density of the light-emitting chips 102 in the second region 10B, and a row of light-emitting chips 102 in the first region 10A and a row of light-emitting chips 102 in the second region 10B are arranged in a staggered manner. As for the structure of the laser device 10 in other combinations, reference may be made to the above relevant contents, and the details will not be repeated herein.

In some embodiments, the laser device 10 may include the plurality of light-emitting chips 102 of a same type, and the plurality of light-emitting chips 102 have a same operating parameter. For example, the laser device 10 is a monochromatic laser device (e.g., a laser device emitting blue laser beams), and the laser beams emitted by the plurality of light-emitting chips 102 have a same color. The operating parameter of the light-emitting chip 102 will be described later.

In some other embodiments, the laser device 10 may include a plurality of types of light-emitting chips 102, and the operating parameters of different types of light-emitting chips 102 may be different. Different types of light-emitting chips 102 generate different amounts of heat when emitting laser beams. For example, in a case where the laser device 10 includes a two-color laser device or a multi-color laser device, the plurality of light-emitting chips 102 emit laser beams of two or three colors. Here, the light-emitting chips 102 may be distinguished according to the colors of the laser beams emitted by the light-emitting chips 102. For example, the light-emitting chip 102 emitting the red laser beam is referred to as a red light-emitting chip, the light-emitting chip 102 emitting the green laser beam is referred to as a green light-emitting chip, and the light-emitting chip 102 emitting the blue laser beam is referred to as a blue light-emitting chip.

In a case where the laser device 10 includes the plurality of types of light-emitting chips 102, a relationship between the heat generated when the plurality of light-emitting chips 102 emit laser beams may be determined based on the operating parameters of the light-emitting chips 102 in the laser device 10, and the plurality of light-emitting chips 102 are arranged according to the relationship between the heat.

In some examples, the operating parameters of the light-emitting chips 102 in the first region 10A are less than the operating parameters of the light-emitting chips 102 in the second region 10B. The operating parameter of the light-emitting chip 102 refers to a parameter that affect the operating temperature of the light-emitting chip 102 when the light-emitting chip 102 emits the laser beam. For example, the operating parameter includes at least one of a photothermal conversion efficiency, a power, or a wavelength of the emitted laser beam. In this way, the light-emitting chips 102 that generate high heat may be arranged in the second region 10B, and light-emitting chips 102 that generate low heat may be arranged in the first region 10A, thereby avoiding the heat accumulation in the first region 10A.

Here, the photothermal conversion efficiency refers to an efficiency of converting optical energy into heat energy by the light-emitting chip 102 when the light-emitting chip 102 emits the laser beam. The higher the photothermal conversion efficiency, the higher the heat generated when the light-emitting chip 102 emits the laser beam. The higher the power of the light-emitting chip 102, the higher the luminance of the emitted laser beam, and the higher the heat generated when the light-emitting chip 102 emits the laser beam. The greater the wavelength of the emitted laser beam, the higher the heat generated when the light-emitting chip 102 emits the laser beam. For example, the heat generated when the red light-emitting chip emits a laser beam, the heat generated when the green light-emitting chip emits a laser beam, and the heat generated when the blue light-emitting chip emits a laser beam decrease in sequence.

In some embodiments, the operating parameter includes the photothermal conversion efficiency. In this case, a photothermal conversion efficiency of each of the plurality of light-emitting chips 102 in the first region 10A is less than a photothermal conversion efficiency of each of the plurality of light-emitting chips 102 in the second region 10B.

In some other embodiments, the operating parameter includes the wavelength of the emitted laser beam. In this case, a wavelength of the laser beam emitted by each of the plurality of light-emitting chips 102 in the first region 10A is less than a wavelength of the laser beam emitted by each of the plurality of light-emitting chips 102 in the second region 10B. For example, the light-emitting chips 102 in the first region 10A emit at least one green or blue laser beam, and the light-emitting chips 102 in the second region 10B emit the red laser beam.

Of course, the wavelength of the laser beams emitted by some light-emitting chips 102 in the first region 10A may also be equal to the wavelength of the laser beams emitted by some light-emitting chips 102 in the second region 10B, as long as the total heat generated by all light-emitting chips 102 in the first region 10A is less than the total heat generated by all light-emitting chips 102 in the second region 10B. For example, in an example where the operating parameter includes the wavelength of the emitted laser beam, in a case where the laser device 10 includes three types of light-emitting chips 102, the three types of light-emitting chips 102 are referred to as a first light-emitting chip, a second light-emitting chip, and a third light-emitting chip according to the wavelength of the emitted laser beam, respectively. The wavelength of the laser beam emitted by the first light-emitting chip is greater than the wavelength of the laser beam emitted by the second light-emitting chip, and the wavelength of the laser beam emitted by the second light-emitting chip is greater than the wavelength of the laser beam emitted by the third light-emitting chip. The first light-emitting chips are arranged in the second region 10B. After finishing arranging the first light-emitting chips, if there is still an empty region in the second region 10B, the second light-emitting chips are arranged in the empty region. If all the second light-emitting chips cannot be arranged in the second region 10B, the remaining of the second light-emitting chips are arranged in the first region 10A, and the third light-emitting chips are arranged in the first region 10A.

In some embodiments, a row of light-emitting chips 102 may include different types of light-emitting chips 102, and in the row of light-emitting chips 102, light-emitting chips 102 that generate low heat may be arranged at the positions proximate to the middle of the row of light-emitting chips 102, and the light-emitting chips 102 that generate high heat may be arranged at the positions proximate to both ends (e.g., the head end or the tail end) of the row of light-emitting chips 102. Alternatively, different types of light-emitting chips 102 may also be arranged in a row of light-emitting chips 102 in a staggered manner.

For example, referring to FIG. 17, the first row of light-emitting chips 102 include six red light-emitting chips. The second row of light-emitting chips 102 may include green light-emitting chips and blue light-emitting chips. For example, the second row of light-emitting chips 102 include four green light-emitting chips and three blue light-emitting chips. In this case, the arrangement manner of the second row of light-emitting chips 102 may be that the green light-emitting chips are adjacently arranged, and the blue light-emitting chips are adjacently arranged. For example, the first to fourth light-emitting chips 102 in the second row are blue light-emitting chips, and the fifth to seventh light-emitting chips 102 in the second row are green light-emitting chips. Alternatively, the arrangement manner of the light-emitting chips 102 in the second row may be that the green light-emitting chips and the blue light-emitting chips are arranged in a staggered manner. For example, in the second row of light-emitting chips 102, the light-emitting chips 102 in the second column, the third column, the fifth column, and the sixth column are blue light-emitting chips, and the light-emitting chips 102 in the first column, the fourth column, and the seventh column are green light-emitting chips.

It will be noted that the present disclosure does not limit the number of types of light-emitting chips 102 included by a row of light-emitting chips 102 and the proportions of different types of light-emitting chips 102 in the plurality of light-emitting chips 102. For example, referring to FIG. 16, in a case where the first row of light-emitting chips 102 include seven red light-emitting chips and the second row of light-emitting chips 102 include six red light-emitting chips, the third row of light-emitting chips 102 may include six blue light-emitting chips, and the fourth row of light-emitting chips 102 may include seven green light-emitting chips. Alternatively, in this case, the third row of light-emitting chips 102 may include six blue light-emitting chips, and the fourth row of light-emitting chips 102 may include one blue light-emitting chip and six green light-emitting chips.

In some embodiments, in a case where the laser device 10 includes a two-color or multi-color laser device, different types of light-emitting chips 102 in the laser device 10 are configured to emit light in a time-division manner, so as to sequentially provide the illumination beams of different colors. In this case, the plurality of light-emitting chips 102 may be arranged according to the difference between light-emitting durations of different types of light-emitting chips 102 during a display period of a frame of an image. For example, the light-emitting chips 102 with a less light-emitting duration during a display period of a frame of an image may be arranged in the first region 10A, so as to reduce the heat generated by the light-emitting chips 102 in the first region 10A.

As shown in FIG. 19, the laser device 10 further includes a collimating lens group 107 located on a side of the frame 1012 away from the base plate 1011, and the collimating lens group 107 includes a plurality of collimating lenses 1070 arranged in a plurality of rows. The plurality of collimating lenses 1070 correspond to the plurality of light-emitting chips 102 and each are configured to collimate the laser beam emitted by the corresponding light-emitting chip 102.

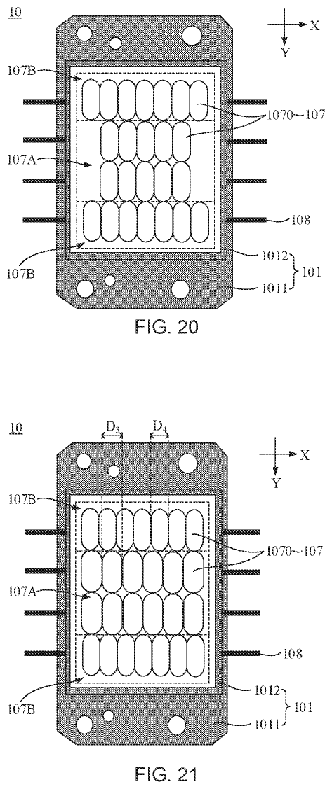

The arrangement manner of the plurality of collimating lenses 1070 may correspond to the arrangement manner of the plurality of light-emitting chips 102. The collimating lenses 1070 corresponding to the light-emitting chips 102 in the first region 10A are located in a third region 107A (as shown in FIG. 20) of the collimating lens group 107, and the collimating lenses 1070 corresponding to the light-emitting chips 102 in the second region 10B are located in the fourth region 107B (as shown in FIG. 20) of the collimating lens group 107. The plurality of collimating lenses 1070 satisfy at least one of the following: the number of collimating lenses 1070 in the third region 107A is less than the number of collimating lenses 1070 in the fourth region 107B; or, a center distance between two adjacent collimating lenses 1070 in a same row in the third region 107A is greater than or equal to a center distance between two adjacent collimating lenses 1070 in a same row in the fourth region 107B.

For example, the arrangement manner of the collimating lenses 1070 is similar to that of the plurality of light-emitting chips 102. In this way, the laser beams emitted by the plurality of light-emitting chips 102 may be collimated by the plurality of collimating lens 1070, so that the laser device 10 may operate normally.

It will be noted that, the center distance between the two collimating lenses 1070 may refer to a distance between center points of orthogonal projections of the two collimating lenses 1070 on the base plate 1011. In a case where a vertex of a convex arc surface of the collimating lens 1070 coincides with the center point of the corresponding orthogonal projection, the center distance between the two collimating lenses 1070 refers to a distance between the vertices of the convex arc surfaces of the two collimating lenses 1070.

In some embodiments, the number of collimating lenses 1070 in the third region 107A is less than the number of collimating lenses 1070 in the fourth region 1073, and the center distance between two adjacent collimating lenses 1070 in a same row in the third region 107A is equal to the center distance between two adjacent collimating lenses 1070 in a same row in the fourth region 107B. Correspondingly, the arrangement manner of the plurality of light-emitting chips 102 corresponding to the plurality of collimating lenses 1070 is that the number of light-emitting chips 102 in the first region 10A is less than the number of light-emitting chips 102 in the second region 10B, and the arrangement density of the light-emitting chips 102 in the first region 10A is less than the arrangement density of the light-emitting chips 102 in the second region 10B.

For example, in a case where the arrangement manner of the plurality of light-emitting chips 102 is shown in FIG. 10, for the arrangement manner of the plurality of collimating lenses 1070 in the collimating lens group 107, reference may be made to FIG. 20. As shown in FIG. 20, the first row and the fourth row of collimating lenses 1070 are located in the fourth region 107B of the collimating lens group 107 and are configured to collimate the laser beams emitted by the first row and the fourth row of light-emitting chips 102 in FIG. 10. The second row and the third row of collimating lenses 1070 are located in the third region 107A of the collimating lens group 107 and are configured to collimate the laser beams emitted by the second row and the third row of light-emitting chips 102 in FIG. 10.

In some other embodiments, the number of collimating lenses 1070 in the third region 107A is less than the number of collimating lenses 1070 in the fourth region 107B, and the center distance between two adjacent collimating lenses 1070 in the same row in the third region 107A is greater than the center distance between two adjacent collimating lenses 1070 in a same row in the fourth region 107B. In this case, as shown in FIG. 21, the plurality of collimating lenses 1070 are arranged in a shape of a rectangle. That is to say, an outer edge of the arrangement shape of the plurality of collimating lenses 1070 is in a shape of a rectangle.

In some embodiments, in the row direction, a width of the collimating lens 1070 in the third region 107A is greater than a width of the collimating lens 1070 in the fourth region 107B. For example, as shown in FIGS. 13 and 21, in a case where the arrangement length of a row of light-emitting chips 102 in the first region 10A is equal to the arrangement length of a row of light-emitting chips 102 in the second region 10B, edges of adjacent collimating lenses 1070 in a same row may be in contact with each other, and, in the row direction, a width D₃ of the collimating lens 1070 in the third region 107A is greater than a width D₄ of the collimating lens 1070 in the fourth region 107B, so that a row of collimating lenses 1070 in the third region 107A may be closely arranged in the row direction.

In this way, it is conducive to reducing the difficulty of arranging the collimating lens group 107. Moreover, it is possible to increase an area of the orthogonal projection of the collimating lens 1070 in the third region 107A, so that the collimating lenses 1070 in the third region 107A may receive more laser beams from the light-emitting chips 102 in the first region 10A, thereby improving the collimating effect of the collimating lens group 107 on the laser beams emitted by the light-emitting chips 102 in the first region 10A.

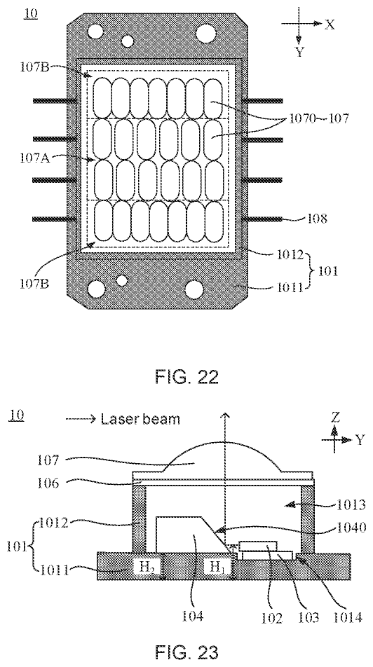

In some other embodiments, the plurality of collimating lenses 1070 have orthogonal projections with a same shape and size. For example, as shown in FIGS. 13 and 22, in a case where the arrangement length of a row of light-emitting chips 102 in the first region 10A is equal to the arrangement length of a row of light-emitting chips 102 in the second region 10B, if the plurality of collimating lenses 1070 have orthogonal projections with a same shape and size, there is a gap between adjacent collimating lenses 1070 in the row of collimating lenses 1070 in the third region 107A. In this way, the consistency of the plurality of collimating lenses 1070 is high. Moreover, the light outside the laser device 10 may enter the laser device 10 through the gaps between the collimating lenses 1070, so as to form the illumination beams together with the laser beams emitted by the light-emitting chips 102, thereby increasing the luminance of the illumination beams and improving the display effect of the projection image.

For other arrangement manners of the plurality of collimating lenses 1070 in the collimating lens group 107, reference may be made to the above arrangement manner of the plurality of light-emitting chips 102, and details will not be repeated herein.

In some embodiments, in a case where the wavelength of the laser beam emitted by the light-emitting chip 102 in the first region 10A is greater than the wavelength of the laser beam emitted by the light-emitting chip 102 in the second region 10B, a radius of curvature of the collimating lens 1070 in the third region 107A is less than a radius of curvature of the collimating lens 1070 in the fourth region 107B.

Here, the radius of curvature of the collimating lens 1070 is a reciprocal of a curvature. The less the radius of curvature of the collimating lens 1070 (i.e., the greater the curvature), the more curved the convex arc surface of the collimating lens 1070, and the greater the reduction in the divergence angle of the laser beam passing through the collimating lens 1070, the better the collimating effect.

In a case where the wavelength of the laser beam emitted by at least one light-emitting chip 102 in the first region 10A is greater than the wavelength of the laser beam emitted by the light-emitting chip 102 in the second region 10B, the divergence angle of the laser beam emitted by the at least one light-emitting chip 102 in the first region 10A is greater than the divergence angle of the laser beam emitted by the light-emitting chip 102 in the second region 10B. Therefore, a collimating lens 1070 with a small radius of curvature may be provided for the light-emitting chips 102 emitting the laser beam with a large divergence angle in the first region 10A, so that the collimating lens group 107 may adaptively collimate the laser beams emitted by the plurality of light-emitting chips 102, thereby improving the light-emitting effect of the laser device 10.

In some embodiments, as shown in FIG. 23, the laser device 10 further includes a groove 1014 disposed on the base plate 1011 and located in the accommodating space 1013, and the groove 1014 is configured to accommodate at least one of the plurality of light-emitting chips 102.

The heat generated when the light-emitting chip 102 in the groove 1014 emits a laser beam may be dissipated to the outside through the base plate 1011 proximate to the groove 1014, and a conduction path of the heat generated by the light-emitting chip 102 is a thickness of a portion of the base plate 1011 corresponding to the groove 1014. Since the thickness of the portion of the base plate 1011 at the light-emitting chip 102 is reduced by providing the groove 1014, the conduction path of the heat generated by the light-emitting chip 102 is short, and the heat may be rapidly transmitted to the outside. In this way, by providing the groove 1014 on the base plate 1011, it is possible to improve the heat dissipation efficiency of the light-emitting chip 102, reduce the probability of thermal damage of the light-emitting chips 102 due to heat accumulation, and thus improve the reliability of the laser device 10.

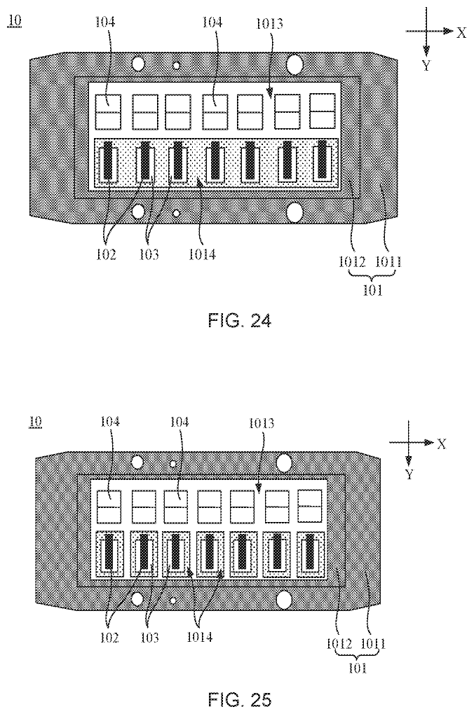

In some examples, the laser device 10 includes a groove 1014. For example, as shown in FIG. 23, the groove 1014 accommodates a light-emitting chip 102. Alternatively, as shown in FIG. 24, the groove 1014 accommodates a plurality of light-emitting chips 102.

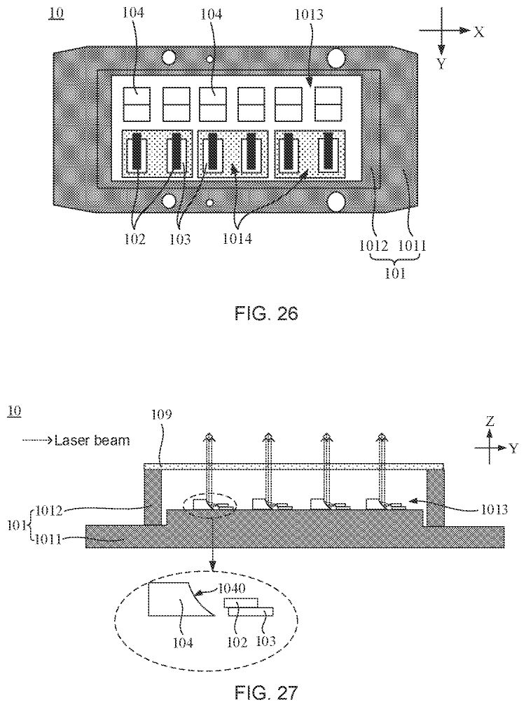

In some other examples, the laser device 10 includes a plurality of grooves 1014 corresponding to the plurality of light-emitting chips 102, respectively. For example, as shown in FIG. 25, one of the plurality of grooves 1014 accommodates a light-emitting chip 102. Alternatively, as shown in FIG. 26, one of the plurality of grooves 1014 accommodates two or more light-emitting chips 102.

It will be noted that the number of light-emitting chips 102 accommodated in the plurality of grooves 1014 may be equal or unequal to each other, and the present disclosure is not limited thereto.

In some embodiments, referring to FIGS. 23 and 24, the laser device 10 further includes a plurality of reflecting prisms 104 disposed on the base plate 1011 and located in the accommodating space 1013, and the plurality of reflecting prisms 104 correspond to the plurality of light-emitting chips 102. The reflecting prism 104 is located on a laser-exit side of the corresponding light-emitting chip 102.

The reflecting prism 104 is configured to guide the laser beam emitted by the light-emitting chip 102 to a direction (i.e., the Z direction in FIG. 23) away from the base plate 1011. For example, a surface of the reflecting prism 104 proximate to the corresponding light-emitting chip 102 is a reflecting surface 1040, and the reflecting surface 1040 may reflect the laser beam emitted by the light-emitting chip 102 in the direction away from the base plate 1011.

It will be noted that the laser device 10 may also include one reflecting prism 104, and the reflecting prism 104 has a plurality of reflecting surfaces 1040, so as to correspondingly reflect the laser beams emitted by the plurality of light-emitting chips 102.

In some embodiments, as shown in FIG. 23, a distance H₁ between a laser-exit region of a light-emitting chip 102 and a surface (e.g., the bottom surface) of the base plate 1011 away from the frame 1012 is greater than or equal to a distance H₂ between a surface (e.g., the bottom surface) of the reflecting prism 104 corresponding to the light-emitting chip 102 proximate to the base plate 1011 and the surface of the base plate 1011 away from the frame 1012. The bottom surface of the reflecting prism 104 may be a connecting surface between the reflecting prism 104 and the base plate 1011.

The laser-exit region of the light-emitting chip 102 refers to a region where the light-emitting chip 102 emits a laser beam, and the laser-exit region may be in a shape of a square, a rectangle, a circle, an ellipse, or the like, and the present disclosure does not limit the shape of the laser-exit region. The distance between the laser-exit region and the surface of the base plate 1011 away from the frame 1012 refers to a distance between a point or side of the laser-exit region proximate to the base plate 1011 and the surface of the base plate 1011 away from the frame 1012. For example, in a case where the laser-exit region is in a shape of a rectangle, the distance between the laser-exit region and the base plate 1011 refers to a distance between a side of the laser-exit region proximate to the base plate 1011 and the surface of the base plate 1011 away from the frame 1012.

In some embodiments of the present disclosure, the distance between the laser-exit region of the light-emitting chip 102 and the surface of the base plate 1011 away from the frame 1012 is greater than or equal to the distance between the bottom surface of the reflecting prism 104 corresponding to the light-emitting chip 102 and the surface of the base plate 1011 away from the frame 1012. In this way, the laser beam emitted by the light-emitting chip 102 may be prevented from being blocked by an inner wall of the groove 1014 where the light-emitting chip 102 is located, so that the laser beam emitted by the light-emitting chip 102 may be incident on the reflecting surface 1040 of the reflecting prism 104 corresponding to the light-emitting chip 102, and the laser beam emitted by the light-emitting chip 102 may be reflected and exit from the laser device 10, thereby improving the utilization rate of the laser beam.

In some embodiments, as shown in FIGS. 23 to 26, the plurality of reflecting prisms 104 are disposed outside the groove 1014. In this case, the groove 1014 only needs to accommodate the light-emitting chips 102, and an area of the groove 1014 may be small. In this way, a thick region of the base plate 1011 (that is, a region without providing the groove 1014) may have a large area, so as to prevent the groove 1014 from affecting the strength of the base plate 1011. Of course, the plurality of reflecting prisms 104 may also be disposed in the groove 1014, and the present disclosure is not limited thereto.

In some embodiments, in addition to guiding the laser beam emitted by the light-emitting chip 102 to the direction away from the base plate 1011, the reflecting prism 104 is further configured to collimate the laser beam emitted by the light-emitting chip 102. In this way, the laser device 10 may not be provided with the collimating lens group 107, so as to reduce the components in the laser device 10, which is conducive to the miniaturization design of the laser device 10.

For example, as shown in FIG. 27, the reflecting surface 1040 of the reflecting prism 104 is a concave arc surface. After the light-emitting chip 102 emits the laser beam to the concave arc surface of the corresponding reflecting prism 104, the concave arc surface may adjust the divergence angle of the incident laser beam, so as to collimate the incident laser beam and reflect the collimated laser beam in the direction away from the base plate 1011.

In some embodiments, the plurality of light-emitting chips 102 include one or more first type light-emitting chips and one or more second type light-emitting chips. The first type light-emitting chip is configured to emit a first type laser beam, the second type light-emitting chip is configured to emit a second type laser beam, and a polarization direction of the first type laser beam is perpendicular to a polarization direction of the second type laser beam. The first type laser beam and the second type laser beam exit from the accommodating space 1013 in the direction away from the base plate 1011, so as to form the illumination beams. For example, the first type laser beam includes at least one of the green laser beam or the blue laser beam, the second type laser beam includes the red laser beam. The polarization direction of the green laser beam or the blue laser beam emitted by the light-emitting chip 102 is substantially perpendicular to the polarization direction of red laser beam emitted by the light-emitting chip 102.

In this case, as shown in FIG. 27, the laser device 10 further includes a polarization conversion component 109. The polarization conversion component 109 is located on a side of the plurality of light-emitting chips 102 away from the base plate 1011 and is configured to change the polarization direction of at least one of the first type laser beam or the second type laser beam, so that the polarization direction of the first type laser beam is the same as that of the second type laser beam.

Since the laser beams with different polarization directions have different transmittance when passing through optical components (e.g., the projection lens 3) in the laser projection apparatus 1000, if the illumination beams provided by the laser device 10 include the laser beams with a plurality of polarization directions, the projection image displayed may have a color cast problem and the display effect may be affected after the illumination beams are modulated by the light modulation assembly 2 and projected by the projection lens 3. However, in some embodiments of the present disclosure, the polarization direction of the first type laser beam is the same as that of the second type laser beam through the polarization conversion component 109, and the polarization directions of the laser beams in the illumination beams are same, so that the transmittance of the illumination beams passing through the optical components is same, which avoids the color cast problem in the projection image displayed by the laser projection apparatus 1000, thereby improving the display effect of the projection image.

In some embodiments, the polarization conversion component 109 includes a wave plate located on the side of the frame 1012 away from the base plate 1011, and the accommodating space 1013 is defined between the wave plate, the frame 1012, and the base plate 1011. In this way, water and oxygen outside the laser device 10 may be prevented from corroding the plurality of light-emitting chips 102, thereby prolonging the service life of the plurality of light-emitting chips 102 and improving the light-emitting effect of the plurality of light-emitting chips 102. Moreover, by using the polarization conversion component 109 to close the accommodating space 1013 directly, it is possible to reduce the number of components in the laser device 10, which facilitates the miniaturization of the laser device 10.

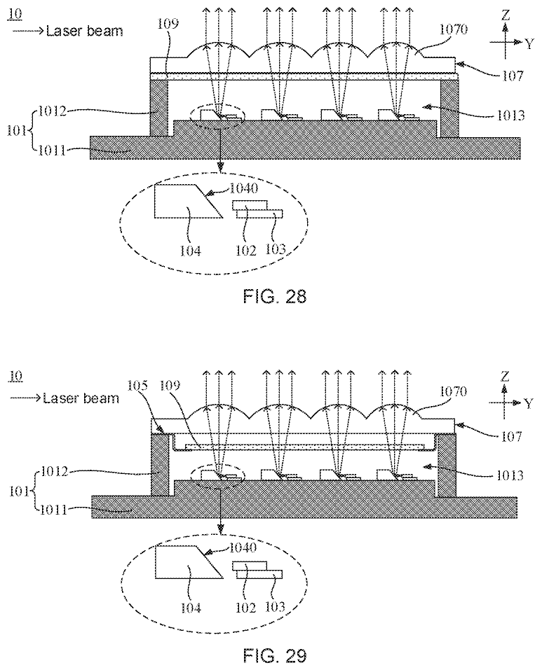

In some embodiments, as shown in FIG. 28, in a case where the laser device 10 includes the polarization conversion component 109, the laser device 10 further includes a collimating lens group 107 disposed on a side of the polarization conversion component 109 away from the base plate 1011. For the structure and function of the collimating lens group 107, reference may be made to the above relevant contents, and details will not be repeated herein.

In some examples, as shown in FIG. 28, an edge of the polarization conversion component 109 is connected to the side of the frame 1012 away from the base plate 1011, so as to close the accommodating space 1013.

In some other examples, the polarization conversion component 109 defines the accommodating space 1013 by other components.

For example, as shown in FIG. 29, the laser device 10 further includes a cover plate 105 in a shape of a ring, and an outer edge of the cover plate 105 is fixed to the surface of the frame 1012 away from the base plate 1011, and the edge of the polarization conversion component 109 is fixed to an inner edge of the cover plate 105. In this way, the polarization conversion component 109 and the cover plate 105 jointly close the accommodating space 1013. In this case, the collimating lens group 107 is located on a side of the cover plate 105 away from the base plate 1011.

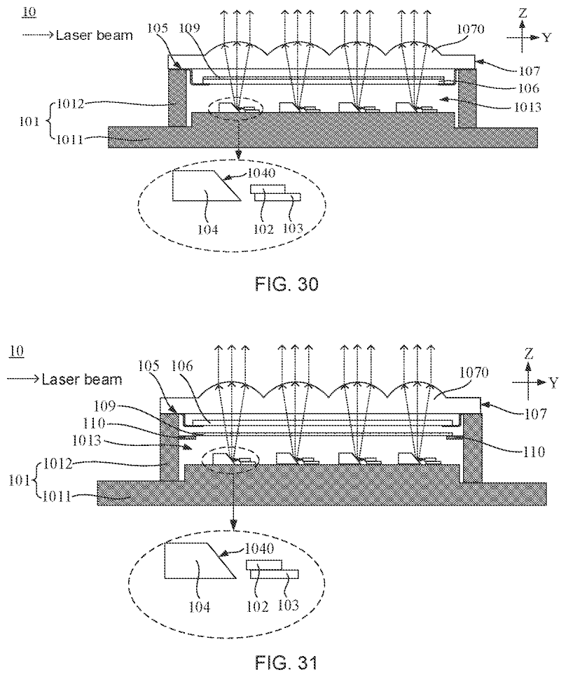

For another example, as shown in FIG. 30, in addition to the cover plate 105, the laser device 10 further includes a light-transmitting layer 106. In this case, the inner edge of the cover plate 105 is indirectly connected to the edge of the polarization conversion component 109 but is fixed to an edge of the light-transmitting layer 106. The polarization conversion component 109 is disposed on a side of the light-transmitting layer 106 away from the cover plate 105. In this case, the light-transmitting layer 106 is closer to the base plate 1011 than the polarization conversion component 109.

For another example, as shown in FIG. 31, in addition to the cover plate 105 and the light-transmitting layer 106, the laser device 10 further includes a boss 110 located in the accommodating space 1013, and an outer edge of the boss 110 is fixed to the frame 1012, and an inner edge of the boss 110 is fixed to the edge of the polarization conversion component 109. In this case, the inner edge of the cover plate 105 is fixed to the edge of the light-transmitting layer 106, and the light-transmitting layer 106 is farther away from the base plate 1011 than the polarization conversion component 109.

It will be noted that the boss 110 may be a boss in a shape of a ring or include a plurality of sub-bosses. For example, in a case where the boss 110 is a boss in a shape of a ring, the boss 110 is continuously disposed on the frame 1012. Alternatively, in a case where the boss 110 includes a plurality of sub-bosses, the plurality of sub-bosses are arranged at intervals on the frame 1012, and the present disclosure is not limited thereto.

The polarization conversion component 109 may adjust the polarization directions of the incident first type laser beam and the second type laser beam to be same in various ways. The following are two possible ways for the polarization conversion component 109 to adjust the polarization directions of the laser beams.

In the first way, the polarization conversion component 109 may adjust the polarization direction of a portion of the incident laser beams. For example, the polarization conversion component 109 deflects the polarization direction of the first type laser beam by 90 degrees without adjusting the polarization direction of the second type laser beam. Alternatively, the polarization conversion component 109 deflects the polarization direction of the second type laser beam by 90 degrees without adjusting the polarization direction of the first type laser beam. Since the polarization direction of the first type laser beam is perpendicular to the polarization direction of the second type laser beam, the polarization conversion component 109 may adjust the polarization directions of the incident first type laser beam and the incident second type laser beam to be same. In such way, the polarization conversion component 109 may be a half-wave plate.

In the second way, the polarization conversion component 109 may adjust the polarization directions of all incident laser beams. For example, the polarization conversion component 109 deflects the polarization direction of the first type laser beam and the polarization direction of the second type laser beam by 45 degrees. In such way, the polarization conversion component 109 may be a quarter-wave plate.

It will be noted that the angle of the polarization direction of the laser beam adjusted by the polarization conversion component 109 is related to a thickness D of the polarization conversion component 109 and a wavelength λ of the laser beam. For example, in a case where the wavelength λ of the laser beam is constant, the greater the thickness of the polarization conversion component 109, the greater the angle of the polarization direction of the laser beam adjusted by the polarization conversion component 109. For example, in a case where the wavelength λ of the laser beam is constant, a thickness of the half-wave plate is greater than that of the quarter-wave plate.

In some embodiments, referring to FIG. 10, the frame 1012 has a plurality of holes on opposite sides of the frame 1012, and the laser device 10 further includes a plurality of conductive pins 108. The plurality of conductive pins 108 pass through the plurality of holes of the frame 1012, respectively, extend into the accommodating space 1013, and are fixed in the plurality of holes, respectively. For example, a conductive pin 108 is correspondingly fixed in a hole. The plurality of conductive pins 108 are configured to be electrically connected to electrodes of the plurality of light-emitting chips 102, so as to transmit current from the external power source to the plurality of light-emitting chips 102, thereby supplying power to the plurality of light-emitting chips 102.

In some embodiments, referring to FIG. 19, the laser device 10 further includes a plurality of heat sinks 103 corresponding to the plurality of light-emitting chips 102. A heat sink 103 is located between the corresponding light-emitting chip 102 and the base plate 1011 and is configured to assist the light-emitting chip 102 to dissipate heat, so that the heat generated by the light-emitting chip 102 may be rapidly transmitted to the base plate 1011. In some embodiments, the plurality of light-emitting chips 102 may share one heat sink 103, and the present disclosure is not limited thereto.

To sum up, the laser projection apparatus 1000 provided by some embodiments of the present disclosure changes at least one of the number or arrangement density of the light-emitting chips 102 in the first region 10A, so that the light-emitting chips 102 in the first region 10A have at least one of the two characteristics of reducing the total heat generated or increasing the heat dissipation area of a single light-emitting chip 102, so as to improve the heat dissipation effect of the light-emitting chips 102 in the first region of the laser device 10 and reduce the probability of thermal damage of the light-emitting chips 102 in the first region 10A due to heat accumulation, thereby improving the reliability of the laser projection apparatus 1000. Moreover, by providing the groove 1014 on the base plate 1011, it is possible to shorten the conduction path of the heat generated by the light-emitting chip 102 located in the groove 1014 and improve the heat dissipation efficiency of the light-emitting chip 102. In addition, by arranging the polarization conversion component 109, it is possible to make the polarization directions of the laser beams in the illumination beams same, so that the transmittance of the illumination beams passing through the optical components is same, thereby improving the display effect of the projection image.

A person skilled in the art will understand that the scope of disclosure in the present disclosure is not limited to specific embodiments discussed above and may modify and substitute some elements of the embodiments without departing from the spirits of this application. The scope of this application is limited by the appended claims.

What is claimed is:

1. A laser projection apparatus, comprising:
a laser source assembly configured to provide illumination beams, the illumination beams including laser beams of three primary colors;
a light modulation assembly configured to modulate the illumination beams with an image signal, so as to obtain projection beams; and
a projection lens configured to project the projection beams into an image; wherein the laser source assembly includes a laser device, and the laser device includes:
a base plate;
at least one frame located on the base plate, at least one accommodating space being defined between the at least one frame and the base plate; and
a plurality of light-emitting chips disposed on the base plate and located in the at least one accommodating space, the plurality of light-emitting chips being configured to emit laser beams; the laser beams exiting from the accommodating space in a direction away from the base plate, so as to constitute the illumination beams;
wherein a region of the base plate located in the at least one accommodating space includes a first region and a second region, the second region is located on at least one side of the first region, two, or more light-emitting chips in the corresponding region are arranged in a row; and
an operating parameter of each light-emitting chip in the first region is less than an operating parameter of each light-emitting chip in the second region, the operating parameter includes at least one of a photothermal conversion efficiency or a wavelength of the emitted laser beam.

2. The laser projection apparatus according to claim 1, wherein the operating parameter includes the wavelength of the emitted laser beam, a wavelength of the laser beam emitted by each of the plurality of light-emitting chips in the first region is less than a wavelength of the laser beam emitted by each of the plurality of light-emitting chips in the second region.

3. The laser projection apparatus according to claim 1, wherein the operating parameter includes the photothermal conversion efficiency, a photothermal conversion efficiency of each of the plurality of light-emitting chips in the first region is less than a photothermal conversion efficiency of each of the plurality of light-emitting chips in the second region.

4. The laser projection apparatus according to claim 1, wherein the number of the light-emitting chips in the first region is less than the number of the light-emitting chips in the second region, and the arrangement density of the light-emitting chips in the first region is equal to the arrangement density of the light-emitting chips in the second region.

5. The laser projection apparatus according to claim 1, wherein the number of the light-emitting chips in the first region is less than or equal to the number of the light-emitting chips in the second region, and the arrangement density of the light-emitting chips in the first region is less than the arrangement density of the light-emitting chips in the second region.

6. The laser projection apparatus according to claim 1, wherein the plurality of light-emitting chips are arranged in a plurality of rows;
the light-emitting chips in the second region include at least two rows of light-emitting chips located at two ends of the plurality of rows of light-emitting chips in a column direction; and
the light-emitting chips in the first region include the light-emitting chips located between the at least two rows of light-emitting chips in the plurality of rows of light-emitting chips.

7. The laser projection apparatus according to claim 6, wherein the laser device satisfies one of following:
in a row direction, an arrangement length of the light-emitting chips in the first region is less than an arrangement length of the light-emitting chips in the second region, and the row direction is perpendicular to the column direction; and
at least one row of light-emitting chips in the first region and at least one row of light-emitting chips in the second region are arranged in a staggered manner.

8. The laser projection apparatus according to claim 1, wherein the laser device further includes a collimating lens group located on a side of the frame away from the base plate; the collimating lens group includes a plurality of collimating lenses arranged in a plurality of rows, the plurality of collimating lenses correspond to the plurality of light-emitting chips, and the plurality of collimating lenses each are configured to collimate the laser beam emitted by the corresponding light-emitting chip;
the collimating lenses corresponding to the light-emitting chips in the first region are located in a third region of the collimating lens group, and the collimating lenses corresponding to the light-emitting chips in the second region are located in a fourth region of the collimating lens group; the plurality of collimating lenses satisfy at least one of following:
a number of the collimating lenses in the third region is less than a number of collimating lenses in the fourth region, and a center distance between two adjacent collimating lenses in a same row in the third region is greater than or equal to a center distance between two adjacent collimating lenses in a same row in the fourth region; or
the number of the collimating lenses in the third region is less than or equal to the number of collimating lenses in the fourth region, and the center distance between two adjacent collimating lenses in a same row in the third region is greater than the center distance between two adjacent collimating lenses in a same row in the fourth region.

9. The laser projection apparatus according to claim 8, wherein the number of the collimating lenses in the third region is less than the number of the collimating lenses in the fourth region, and the center distance between two adjacent collimating lenses in a same row in the third region is equal to the center distance between two adjacent collimating lenses in a same row in the fourth region.

10. The laser projection apparatus according to claim 9, wherein the plurality of collimating lenses have orthogonal projections with a same shape and size on the base plate.

11. The laser projection apparatus according to claim 8, wherein the number of collimating lenses in the third region is less than or equal to the number of collimating lenses in the fourth region, and the center distance between two adjacent collimating lenses in a same row in the third region is greater than the center distance between two adjacent collimating lenses in a same row in the fourth region.

12. The laser projection apparatus according to claim 11, wherein in a row direction, a width of the collimating lenses in the third region is greater than a width of the collimating lenses in the fourth region.

13. The laser projection apparatus according to claim 8, wherein a radius of curvature of the collimating lenses in the third region is less than a radius of curvature of the collimating lenses in the fourth region.

14. The laser projection apparatus according to claim 1, wherein the laser device further includes at least one groove disposed on the base plate and located in the accommodating space, and the groove is configured to accommodate at least one of the plurality of light-emitting chips.

15. The laser projection apparatus according to claim 14, wherein the at least one groove includes a plurality of grooves corresponding to the plurality of light-emitting chips.

16. The laser projection apparatus according to claim 14, wherein the laser device further includes a plurality of reflecting prisms disposed on the base plate and located in the accommodating space, and the plurality of reflecting prisms correspond to the plurality of light-emitting chips; the reflecting prism is located on a laser-exit side of the corresponding light-emitting chip and located outside the groove; and
a distance between a laser-exit region of the light-emitting chip and a surface of the base plate away from the frame is greater than or equal to a distance between a surface of the corresponding reflecting prism proximate to the base plate and the surface of the base plate away from the frame.

17. The laser projection apparatus according to claim 1, wherein
the plurality of light-emitting chips include a first type light-emitting chip and a second type light-emitting chip, the first type light-emitting chip is configured to emit a first type laser beam, and the second type light-emitting chip is configured to emit a second type laser beam, a polarization direction of the first type laser beam is perpendicular to a polarization direction of the second type laser beam; and
the laser device further includes a polarization conversion component, the polarization conversion component is located on a side of the plurality of light-emitting chips away from the base plate and configured to change the polarization direction of at least one of the first type laser beam or the second type laser beam, so that the polarization direction of the first type laser beam is same as the polarization direction of the second type laser beam.

18. The laser projection apparatus according to claim 17, wherein the polarization conversion component includes a wave plate located on a side of the frame away from the base plate, and the accommodating space is defined between the wave plate, the frame, and the base plate.

19. The laser projection apparatus according to claim 17, wherein the laser device satisfies one of following:
the laser device further includes a cover plate in a shape of a ring, and an outer edge of the cover plate is fixed to a surface of the frame away from the base plate, and an edge of the polarization conversion component is fixed to an inner edge of the cover plate; and
the laser device further includes:
the cover plate in a shape of a ring, the outer edge of the cover plate being fixed to the surface of the frame away from the base plate; and
a light-transmitting layer, an edge of the light-transmitting layer being fixed to the inner edge of the cover plate, and the polarization conversion component being disposed on a side of the light-transmitting layer away from the cover plate; and
the laser device further includes:
the cover plate in a shape of a ring, the outer edge of the cover plate being fixed to the surface of the frame away from the base plate;
the light-transmitting layer, the edge of the light-transmitting layer being fixed to the inner edge of the cover plate; and
a boss located in the accommodating space, an outer edge of the boss being fixed to the frame, and an inner edge of the boss being fixed to the edge of the polarization conversion component.

20. The laser projection apparatus according to claim 17, wherein the polarization conversion component satisfies one of following:
the polarization conversion component is configured to deflect the polarization direction of one of the first type laser beam and the second type laser beam by 90 degrees; and
the polarization conversion component is configured to deflect the polarization direction of the first type laser beam by 45 degrees and deflect the polarization direction of the second type laser beam by 45 degrees.
